(19) United States
(12) Patent Application Publication
(10) Pub. No.: US 2015/0320196 A1
(43) Pub. Date: Nov. 12, 2015

(54) PORTABLE WORK SURFACE TOOL

(71) Applicant: TreMax Enterprises, LLC, Oakland, NJ (US)

(72) Inventor: Steven Polizzi, Oakland, NJ (US)

(73) Assignee: TreMax Enterprises, LLC, Oakland, NJ (US)

(21) Appl. No.: 14/705,119

(22) Filed: May 6, 2015

Related U.S. Application Data
(60) Provisional application No. 61/996,475, filed on May 9, 2014.

(51) Int. Cl. A47B 5/04; A47B 17/00; H01L 31/042; A47B 5/02; H02J 7/35; A47B 5/06; A47B 13/08

(52) U.S. Cl. CPC A47B 5/04; A47B 5/06; A47B 17/00; A47B 13/083; A47B 5/02; H02J 7/35; H01L 31/042

(57) ABSTRACT

A portable work surface tool includes a body member having top and bottom portions, wherein the top portion defines a work surface, at least one fastening element operatively associated with the body member, wherein the fastening element is configured for secure engagement with a fixed portion of a vertical structure.

### CROSS-REFERENCE TO RELATED APPLICATIONS

This application claim the benefit of U.S. Provisional Patent Application Ser. No. 61/996,475, filed May 9, 2014.

### STATEMENT REGARDING FEDERALLY SPONSORED RESEARCH OR DEVELOPMENT

Not Applicable

### FIELD OF THE INVENTION

The present invention relates to furniture and particularly to a portable work surface tool.

### BACKGROUND OF THE INVENTION

Furniture represents a class of movable objects that are typically used to support various human activities including writing, sitting, sleeping and the like. Furniture is also used to hold objects at a convenient height for work or to store things.

There is a need for a portable work surface tool that can be securely mounted to a vertically oriented structure, and provide a stable work surface for the user. There is a need for a portable work surface tool having a work surface that can be adjusted by the user to a desired height. There is a further need for a portable work surface tool that can be folded into a compact form to enhance ease of carry, transport and storage of the tool and its accessories.

### BRIEF SUMMARY OF THE INVENTION

The present invention relates generally to a portable work surface tool that is optionally foldable. The present portable tool is configured for secure (removably) mounting on a fixed vertical structure such as, for example, a fence, to support a work surface in a stable manner. The present portable tool may further be configured to allow the user to adjust the desired height of the work surface. The present portable tool is designed for ease of use and versatility for a range of activities requiring a work surface. Preferably, the present portable, foldable work surface tool is in the form of a sports scoring tool, one particular embodiment of which being a baseball and/or softball and/or stickball game scoring tool.

Other particular embodiments include a scoring tool for other sports where statistics are kept or recorded including: hockey, track and field, football, basketball, lacrosse, soccer, etc.

Additional embodiments include applications in fields other than sports including, for example, construction, medical, and/or any other field requiring a portable work surface.

In one embodiment of the present invention, the present portable tool may include the following preferred features:
(a) clips, hooks, suction cups, or other fasteners, and tethers therefore to secure the tool to a vertical support structure.
(b) slots, integral to the tool, for the tethers and associated fasteners.
(c) adjustable hangers or hooks that will easily clip onto virtually any chain link fence of any size, on any field, at any comfortable height, optionally being metallic clips which may be secured to the frame with magnets when not in use, and optionally include fasteners that are optionally interchangeable therewith such as, for example, suction cups that can secure and/or fasten the embodiment to a flat, vertical surface or wall, and optionally may further include auxiliary support aspects, such as, without limitation, a mount to secure to a non-permanent structure such as a tripod to expand the embodiments versatility, portability, and expand its applications.
(d) Folding supports, either legs, or hinges which open from within the frame and snap into place, to provide support against a fence or other vertical structure, create an instant worktop/workstation; or, in the alternative, a lower portion (the “bottom portion” of some preferred embodiments) of approximately the same width and depth as the top surface of the invention tool in a hinged relationship with the top portion so that on opening the tool into an operating position, the lower portion acts as a broad single support;
(e) optionally, solar power strips for providing power to rechargeable batteries, and various tally counters;
(f) optionally incorporates digital counter(s), preferably at least two (2) resettable digital pitch counters for home and away teams visible through liquid crystal display windows in the upper right and left corners, which may be utilized for other counting purposes in some embodiments if so desired;
(g) optionally removable and/or rechargeable power supply stored on the underside within the frame;
(h) optional cable for tablet or smart phone charging;
(i) optionally built in handle for portability and comfort;
(j) optional wet or dry erase surface on one side for notes, rosters, or to record desired information, such as without limitation, pitchers/pitch counts etc.;
(k) optional built in pencil/paper clamp for scorecards or rosters & notes;
(l) optional textured/rubberized surface on a portion of the top surface not occupied by the wet or dry erase surface to provide nonslip surface for tablets and smart phones;
(m) optionally, the top surface can be adjustably angled for optimal viewing from sun glare;
(n) optional storage space inside for pencils, scorecards or scorebook, tablet and/or battery;
(o) optionally built in pencil sharpener within the frame;
(p) in the closed, folded position, carries like a briefcase, very portable and very lightweight;
(q) sheet metal components of some embodiments may be anodized or powder coated for longevity, durability, and to provide custom colors and/or team colors;
(r) optional convenience cup holder, which may be integrated into the tool or removable;
(s) optional slot to hang the optional, removable cup holder;
(t) components are preferably sealed and weather resistant, more preferably weatherproof;
(u) optional protective surfaces, such as, without limitation, felt or other similar soft surface on the top portion underside and bottom portion interior surface of the tool to aid in protecting any stored contents;
(v) optional elastic keepers to securely hold stored items and/or accessories;
(w) optionally, a weather shield, including without limitation, a sun/rain shield;
(x) optionally an integral latch on the bottom portion or top portion of tool for closure;
(y) optionally a latch receiver on top portion or bottom portion for engagement with the optional latch above; and
(z) optional Bluetooth communication capability for live transmission of scoring to wireless remote scoreboards.

In one aspect of the present invention, there is provided a portable work surface tool, including:
a body member having top and bottom portions, the top portion defining a work surface;
at least one fastening element operatively associated with the body member, the fastening element being configured for secure engagement with a fixed portion of a vertical structure;
at least one leg member extending from the bottom portion of the body member, the leg member being configured for operative engagement with the vertical structure to maintain the work surface in an upwardly-directed orientation;
optionally at least one secondary fastening element secured to the top portion of the body member, the secondary fastening element configured for operative engagement with the vertical structure when the tool is in a non-operative, non-use position and upon disengaging with the vertical structure, allows movement of the tool into a deployed position for use; and
optional attachment cables secured to the tool at the right and left sides of the top surface of the tool for further attachment to the vertical support structure.

### BRIEF DESCRIPTION OF THE DRAWING

The following drawings are illustrative of embodiments of the invention and are not intended to limit the invention as encompassed by the claims forming part of the application.

FIG. 1 is a top plan view of a portable work surface tool in accordance with a first embodiment of the present invention;

FIG. 1a is a top plan view of a portable work surface tool in accordance with a second embodiment of the present invention;

FIG. 1b is a perspective view (in a working position) of a most basic version of one embodiment of the invention in which vertical support attachment cables are used for attachment of the tool to the vertical support structure are used in place of vertical support legs or a bottom portion.

FIG. 1c is a perspective view of the embodiment of FIG. 1b in an in use position with some of the optional features thereon.

FIG. 2 is a partially exploded side view from the left side of a first embodiment of the portable tool in accordance with the present invention;

FIG. 2a is a partially exploded side view from the left side of a second embodiment of the portable tool in accordance with the present invention;

FIG. 2b is a perspective view of the embodiment in FIG. 1b, but viewed in a non-working storage position secured for storage on a vertical support structure.

FIG. 3 is a side view from the right side of a first embodiment of the portable tool in accordance with the present invention;

FIG. 3a is a side view from the right side of a second embodiment of the portable tool in accordance with the present invention;

FIG. 4 is a perspective view of another embodiment of the portable work surface tool mounted on a chain link fence in accordance with another embodiment of the present invention with separate optional elements which may be used thereon being shown;

FIG. 5 is a view of the front, in an open position, of the portable tool of FIG. 4 in accordance with the present invention, mounted to a chain link fence with separate optional elements which may be used thereon being shown;

FIG. 6 is a front plan view of a still another embodiment of the present invention viewed in an open position.

FIG. 7 is a top perspective view of the embodiment of FIG. 6 in a vertical, folded, and closed position for transportation and storage.

FIG. 8 is a top perspective view in a closed, flat, and horizontal position for transportation and storage.

FIG. 9 is a bottom perspective view of the embodiment of FIG. 8 in a folded, closed, and vertical position for transportation and storage.

FIG. 10 is a bottom rear view of the embodiment of FIG. 6 in an open position with the bottom folded down and in view from the rear, ready for use.

FIG. 11 is a right side perspective view of the embodiment of FIG. 6 in a horizontal, folded and closed position for transportation and storage.

FIG. 12 is a right side perspective view of the embodiment in FIG. 6 in an open position, ready for use.

FIG. 13 is a bottom perspective view of the embodiment of FIG. 6 in an open position for use viewing the interior portions of the open case.

FIG. 14 is a rear perspective view of the embodiment of FIG. 6 in an open position and attached to a chain-link fence ready for use.

FIG. 15 is a front view corresponding to the rear view shown in FIG. 14.

FIG. 16 is a top-right side perspective view of the embodiment shown in FIG. 15.

FIG. 17 is a top-left side perspective view of the embodiment shown in FIG. 15.

FIG. 18 is a bottom, rear view of the embodiment of FIG. 12 in a closed position.

FIG. 19 is a front view of the embodiment in FIG. 18 in a closed, horizontal position.

FIG. 20 is a rear view of the embodiment in FIG. 18 in a closed, horizontal position.

FIG. 21 is a front perspective view of an alternate embodiment of the invention wherein in an open working position with the work surface being internal to the tool.

### DETAILED DESCRIPTION OF THE INVENTION

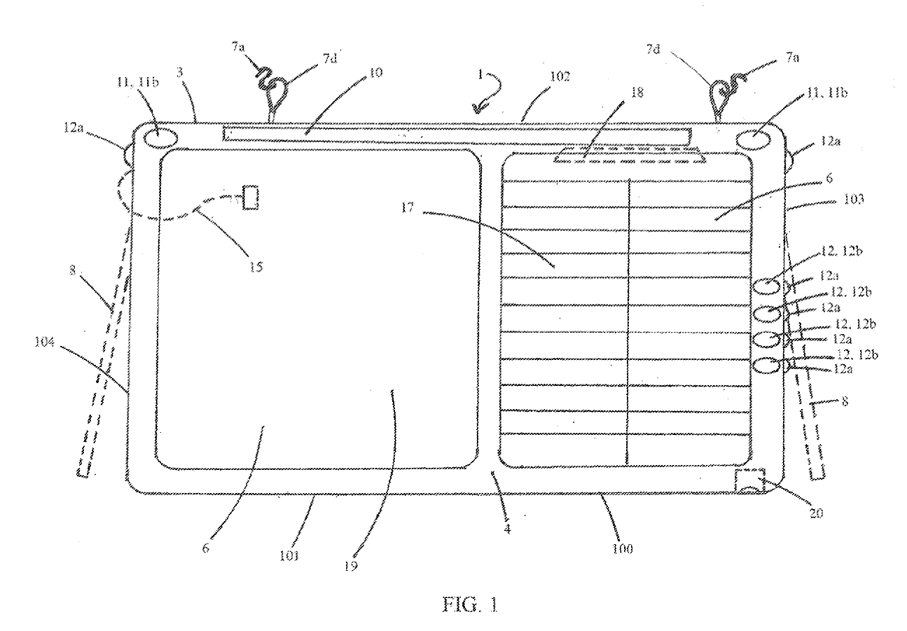

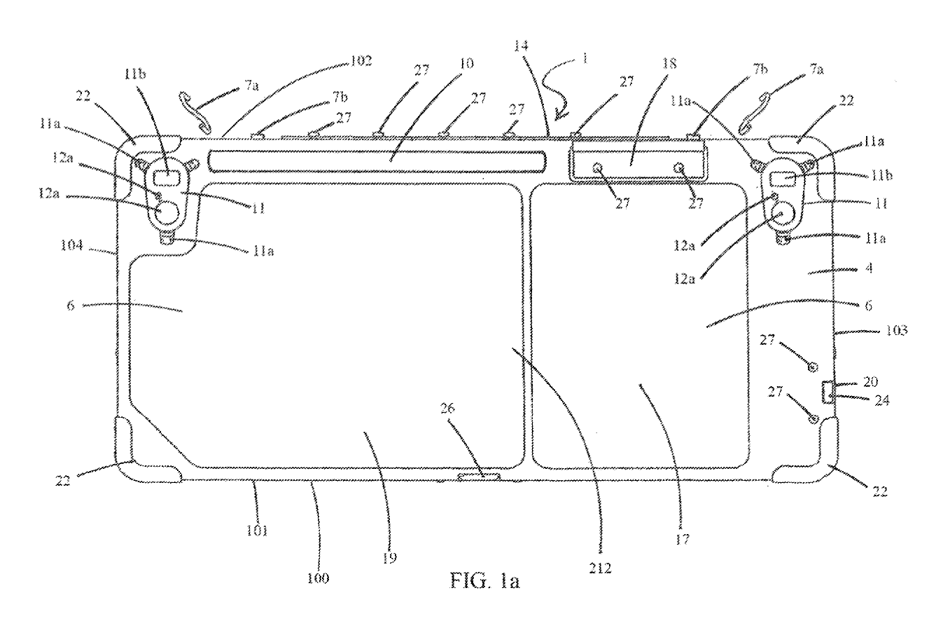

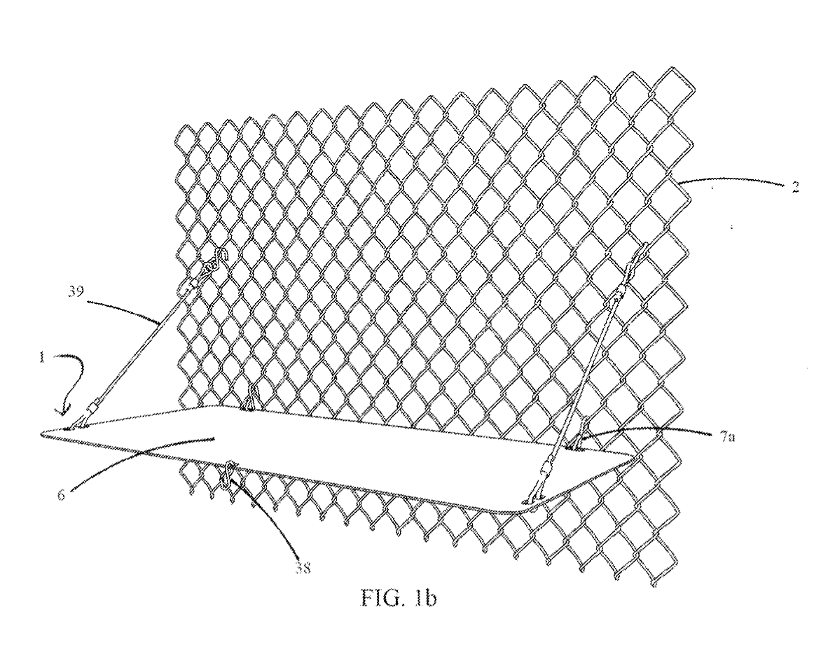

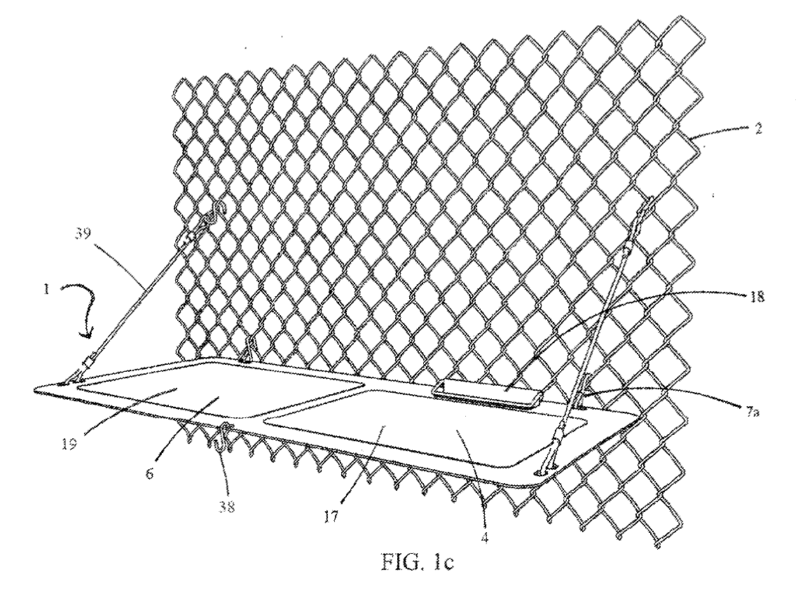

With reference to the accompanying figures, the present invention is generally directed to a portable work surface tool (1I) that is optionally foldable. The present portable tool (1) is configured for secure (but easily removable) mounting on a fixed vertical structure (2) (not shown in FIGS. 1, 1a, 2, 2a, 3, 3a, 6-13, and 18-20) such as, for example, a fence (most preferably a chain link fence, wall, or partition), to support a work surface in a stable manner. The present portable tool (1) may further be configured to allow the user to adjust the desired height or angle of the work surface. The present portable tool (1) is designed for ease of use and versatility for a range of activities requiring a work surface. Preferably, the present portable, foldable work surface tool (1) can be used as an athletic game (including, but not limited to baseball, stickball, and softball) scoring tool. Other non-limiting activities for which the present invention is useful includes, but is not limited to, hockey, track and field, basketball, football, lacrosse, construction sites, medical fields or any other venue or activity where statistics are kept and/or recorded.

The present portable tool (1) can be used by any coach or person scoring a game on the field and for use by local recreation programs, schools, club baseball/softball teams and the like. The simplicity, design, and ease of use of the present portable tool (1) make it convenient and comfortable for any user scoring a ball game, or any other sport or activity where statistics are recorded or kept, by providing a height adjustable workspace for use in combination with either a portable electronic device (such as without limitation, a laptop computer, a tablet, a smartphone, etc.) or a conventional scorebook.

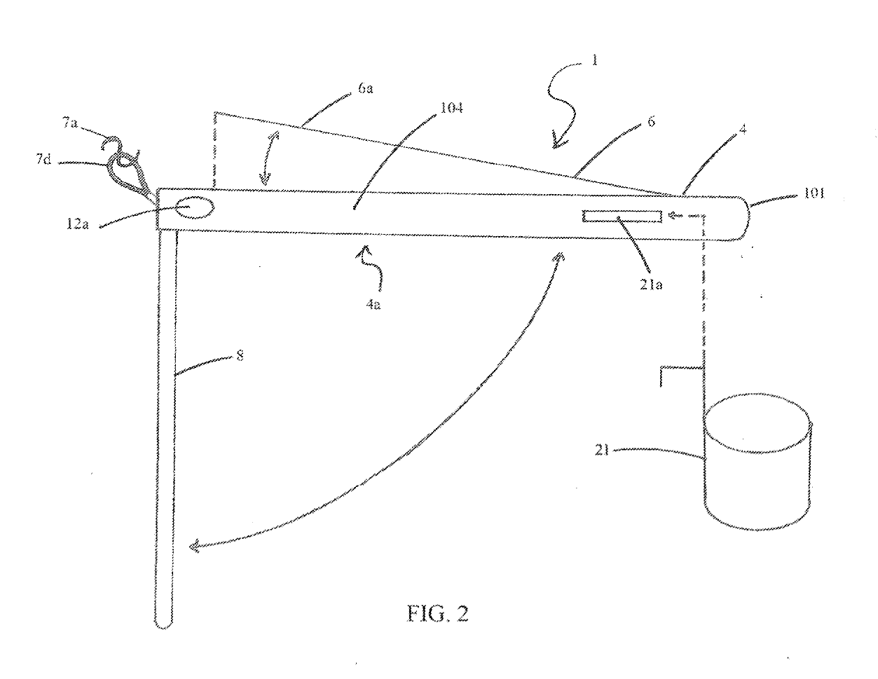

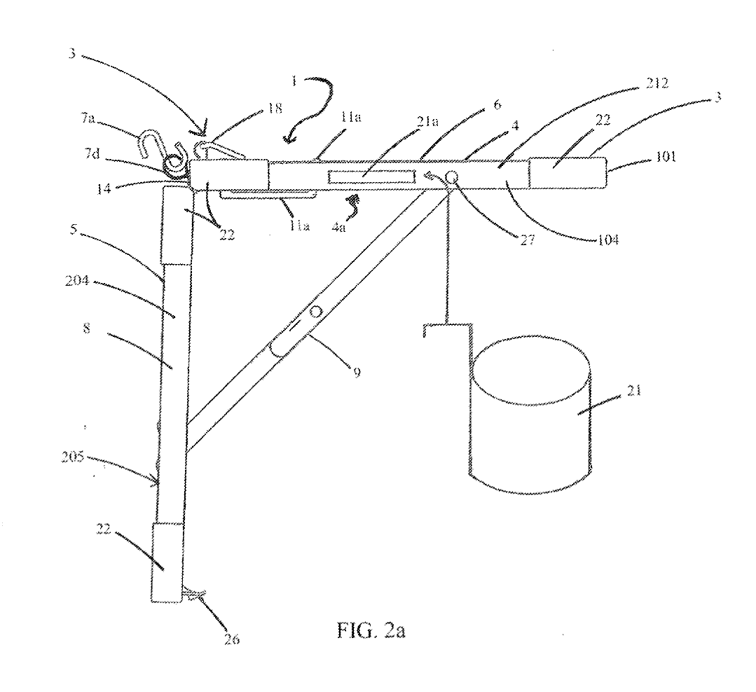

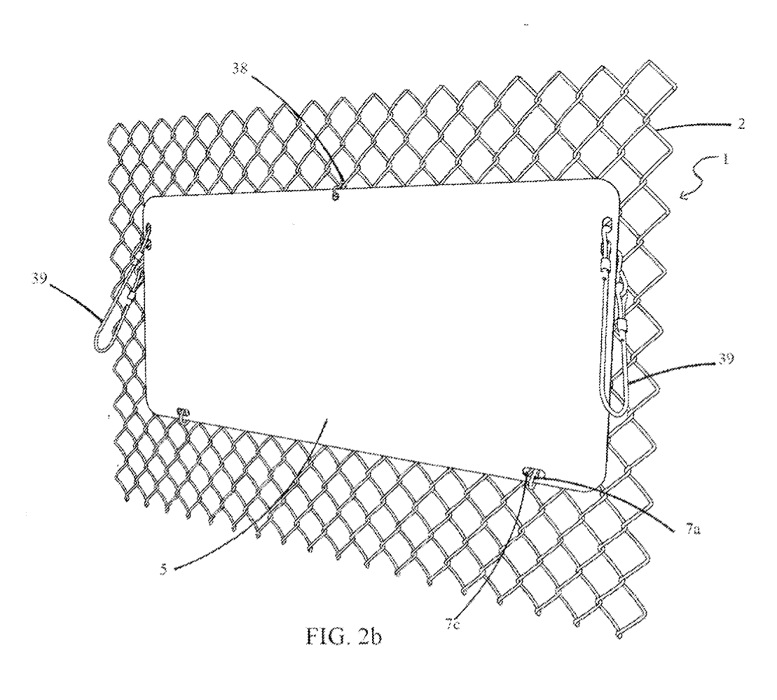

Generally, there is provided a portable work surface tool (1) which includes a body member (3) having a top portion (4) and a top portion underside (42), wherein the top portion (4) defines a work surface (6), which may include an adjustable, angled work surface (6a), the top portion underside (4a) defines optional storage areas and optional receiving areas for collapsible and/or foldable vertical support members (8) and/or support braces (9) (or optionally in addition or optionally in place of either or both of vertical support members (8) and/or support braces (9), may have support cable (39) (shown in FIGS. 1b and 2b)), at least one fastening element (7,7a) operatively associated with the body member (3), wherein the fastening element (7,7a) is configured to secure engagement with a fixed portion of a vertical structure (2), and at least one vertical support member (8) (which may be extending from the top portion underside (4a)), wherein the vertical support member (8) is configured for operative engagement with the vertical structure (2) to maintain the work surface in an upwardly-directed orientation or, (b) in place of the vertical support member (8), a bottom portion (5), dimensioned to be of approximately the same width and depth as the top portion (4) and attached to the top portion (4) by hinge (14) in a manner that resembles a closed attaché case in a closed position and in an open position the bottom portion (5) is the vertical support member (8); or (c) optionally in place of or in addition to either or both of vertical support member (8) and/or bottom portion (5), attachment support cable(s) (39). The fastening element (7) may consist of appropriate hooks (such as, without limitation, the “S” hooks shown in the figures as element (7a)), suction cups, clips or various fasteners directly attached to the body member (3) or attached to tethers (7d) or other suitable connectors attached to the body member (3). In some embodiments, the vertical support member (8) may constitute one or more separate fixed (but foldable and/or collapsible) legs (see FIG. 1). In other embodiments, the vertical support may double as a bottom portion (5) of approximately the same dimensions in length and width as the top portion (4) connecting to the top portion (4) with locking mechanical hinges (9) and attachment hinge (14) attached to internal portions of the top portion underside (4a) and the internal portions of the bottom portion (5), so that upon folding the bottom portion (5) to the top portion (4), the top portion (4) and the bottom portion (5) together form a closed unit resembling a closed attaché case for storage and transportation. References to “internal” herein refer to the space considered “internal to a closed attaché case” when the embodiment of the invention in a closed position resembles an attaché case. In the event that such reference is used in connection with an invention embodiment which does not close to resemble as attaché case, the corresponding placement to the embodiment which does close to resemble an attaché case is intended unless explicitly stated otherwise.

In one preferred embodiment of the present invention, the present portable tool (1) is shown and depicted in FIGS. 1, 2, and 3. In a second preferred embodiment of the present invention, the present portable tool (1) is shown and depicted in FIGS. 1a, 2a, 3a, 4, 5, 6, and 7-20. A very simplified embodiment of the invention is shown in FIGS. 1b, 1c, and 2b. In each of these figures, the invention tool (1) work surface (6) of top portion (4) is depicted as a “right-handed model”. It is to be noted however, that the invention is not limited to right handed models, but includes the corresponding “left-handed models” but for simplification, only the so called “right-handed model” will be further described. The features described below that may differ between the left handed and right handed versions are generally the placement and/or orientation of the textured/rubberized surface (19) and the wet/dry erase board (17) and the pencil/paper clip (18) to accommodate left handed writers. The remaining elements may or may not be reversed with respect to left and right orientation with respect to the right-handed model described below without departing from the spirit of the invention. Those of ordinary skill in the art will readily appreciate the alternative placement of features between these types of models and recognize that the scope of the invention includes each. The preferred embodiments shown in the accompanying FIGS. 1-20 may optionally include (without limitation) the following preferred features:
moveable speed clips or S hooks (as non-limiting examples of a fastening element (7)) that will easily adjust and clip onto virtually any chain link fence (as one non-limiting example of a fixed vertical structure (2)) of any size, on any field, at any comfortable height;
optional openings (7c) (preferably oval) in the rear of the top portion (4) to secure fastening elements (7) or tethers (7d) for the fastening elements (7) and optionally for storage thereof when not in use;
magnetic fasteners (7b), fixed to the portable tool (1), to secure hooks/clips (7s) when the hooks/clips (7a) are not in use;
folding and/or collapsible vertical support members (8) (preferably, without limitation, one or more legs which open from (a) in a first embodiment without a separate frame, the top portion underside (4a), or (b) in a second embodiment either the top portion underside (4a) OR from appropriate portions of the top portion frame (100), including without limitations from top portion frame front (101), (top portion frame rear (102), top portion frame right side (103), and top portion frame left side (104); the legs snap or lock into place (with or without support braces similar to those shown as support braces and/or hinges (9) and hinge connectors (9a); when the vertical support member is bottom portion (5), bottom portion (5) is connected to top portion (4) via hinge (s) (14) located along the back edge of each and suitably mounted so as to allow the top portion (4) and the bottom portion (5) to move in a hinged fashion relative to one another, and when moved to an open position, the bottom portion (5) and top portion (4) snap or lock into place (with or without support braces similar to those shown as support braces and/or hinges (9) and when support braces and/or hinges similar to those shown as support braces and/or hinges (9) are present, they are attached to (a) the top portion underside (4a) or internal portions of top frame (100) as appropriate including appropriate portions of top frame front (101), top frame back (102), top frame right side (103), and/or top frame left side (104) as appropriate and to (b) bottom internal surface (206) or bottom frame (207) internal portions as appropriate, including appropriate portions of bottom portion frame front (207a), bottom portion frame back (207b), bottom portion frame right side (207c), and/or bottom portion frame left side (207d) as appropriate) to provide support against the fixed vertical structure (such as, without limitation, a fence) (2) and create an instant worktop/workstation;
solar power strips (10) are optionally, but preferably provided to obtain power to charge rechargeable batteries, digital primary counters and digital secondary counters (such as without limitation, pitch counters and balls, strikes, inning, and outs counters), etc.; the solar power strips being located on any suitable surface of the portable work surface tool (1) that will be exposed to light during use of the portable work surface tool (1), but preferably (a) on the top surface of top portion (4) along the perimeter of the top portion (4), (b) along the sides of the perimeter of the top portion (4) and/or any suitable surface of the leg member (8) which will be exposed to light when the work surface tool (1) is in use in an opened operating position;
mechanical or digital counters (11, 12), preferably digital counters, such as, without limitation, pitch counters and balls, strikes, inning, and outs counters), having displays visible through suitable display windows (such as, without limitation liquid crystal display windows (11b), (12b)) on the top portion (4) of the unit, operable through the touch of button(s) (12a) conveniently located on the sides of the unit)—(or counters and their respective buttons can be integrated into single pieces having the particular function button and its corresponding display window);
incorporates the aforementioned resettable (preferably digital) primary counter (11,12) and corresponding displays (11b,12b) (preferably two such primary counters, one for each of the home and away teams) (preferably such primary counters are pitch counters for baseball, softball, or stickball use) (preferably visible through liquid crystal display windows) preferably in the right and/or left corners of the top surface of top portion (4) which are furthest removed from the user when work surface tool (1) is in the open position for use and multiple buttons (12a) and corresponding displays (11b,12b) for recording appropriate actions of the teams (preferably four (4) buttons (12) for innings, outs, balls, and strikes in softball, baseball, or stickball, or for recording downs and yards etc. in football or for other suitable information for other sports such as (without limitation) soccer, basketball, gymnastics, hockey, ice skating, competition dancing, track and field, etc.) located on the right side of the unit shown in FIGS. 1-20. Counters (11,12) are secured in place by removable holders (11a) for the purpose of servicing, changing batteries;
optional, but preferable, rechargeable power supply storage (13) on top portion (4) underside (4a) within the top frame (100), although placement thereof on the bottom internal surface (206) is an acceptable alternative
optional, but preferable, tablet or smart phone charging capabilities (15), such as appropriate current converters and cables therefor;
optionally, but preferably, a handle (16), optionally, but preferably, an ergonomic handle, built-in for portability and comfort;
optionally, but preferably, wet-erase or dry-erase surface(s) (17) (hereinafter wet/dry erase surface) on one side of top surface (4) for notes, rosters, or to record any other information (such as without limitation, pitches/pitch counts), preferably on the right side of the top surface of top portion (4) when viewed from the top when the tool (1) in an operating open position for right handed models and preferably on the left side of the top surface of top portion (4) when viewed from the top in an operating open position for left handed models;
optionally, but preferable, pencil/paper clamp (18) for, but not limited to, scorecards or rosters and notes;
optionally, but preferably, a textured/rubberized surface (19) on the top work surface (6) of the top portion (4) in at least a portion of the region not occupied by the wet/dry erase surface (17) to provide a nonslip surface for tablets, smart phones and the like;
optionally, but preferably, a portion or all of the top work surface (6) of the top portion (4) is a surface that can be an adjustably angled surface (6a) so as to reduce sun glare for optimal viewing;
optional, but preferable, storage space located either underneath the top work surface (6) of the top portion (4) and accessed by raising the top work surface (6) of top portion (4) or attached to the top portion underside (4a) or as recessed compartments within the top portion frame and accessed by reaching underneath the frame (100), the storage space being for pencils, scorecards or scorebook, tablet, smart device, etc.;
optionally, but preferably, a built in pencil sharpener (20) within the frame of top portion (4); preferably with pencil sharpener (20) being dual sized for added versatility and flexibility;
optionally, but preferably, a latch (26) (preferably a molded plastic latch) for closure with top portion (4) incorporating the latch opening (26a). The latch preferably also incorporates an internal storage riser/keeper (26b).
optionally, but preferably, the bottom interior portion (206) incorporates a durable (preferably silicone) band (28) or similar strap or belt (with appropriate clasps) to secure stored items.
the portable work surface tool (1) of the present invention, preferably folds so that vertical supports (8) in the first embodiment can be retained within space below the top portion (4) defined by the frame (100) or bottom portion (5) closes up with top portion (4) so as to resemble an attaché case, in either case, as folded or closed, the invention tool (1) can be carried like a briefcase, being very portable and very lightweight while providing storage;
the tool (1) of the present invention can be made of any suitably rugged material, such as, without limitation, metal, plastics, wood, or combinations thereof, and if constructed of sheet metal, the sheet metal is preferably anodized or powder coated for durability, longevity and to provide custom colors and/or team colors; nonetheless, the use of less durable materials is not precluded from the scope of the invention, just much less desirable;
optionally, but preferably, a convenience cup holder (21); and
optionally, but preferably, slotted receiver (21a) for cup holder (21);
preferably all components are sealed and weather resistant, preferably weatherproofed;
optionally, but preferably, all exterior edges are rounded and corners are equipped with molded plastic attachments (22) for safety.
optionally at least one secondary fastening element (38) secured to the top portion of the body member, the secondary fastening element configured for operative engagement with the vertical structure when the tool is in a non-operative non-use position and upon disengaging with the vertical structure, allows movement of the tool into a deployed position for use; and
optional (but required for embodiments not having either support members (8) and bottom portion (5)) at least one, preferably 2, attachment cables (39) secured to the tool (1) at the right and left sides of the top surface of the tool for further attachment to the vertical support structure (2).

With greater reference to the accompanying Figures in which like numbers represent like parts, FIG. 1 shows the top view of one embodiment of the present invention being a portable work station tool (1). The embodiment having a body member (3), being made up of a top portion (4) having an optional top portion frame (100), providing a top work surface (6). The top work surface (6) having a top frame front (101), a top frame back (102), a top frame right side (103), and a top frame left side (104) When the tool does not have a frame (100) (not shown), it has edges corresponding to the top frame and are a top front edge (101a), a top back edge (102a), a top right edge (103*), and a top left edge (104a). Vertical support members (8) which are foldable and for collapsible may be secured to top portion underside (4a) (not shown in FIG. 1) alone (for embodiments with or without having frame (100) or secured to appropriate portions of frame (100) (such as (101, 102, 103, and/or 104)) or both. Tool (1) has optional power strip (10), optional wet/dry erase board (17), optional pencil/paper clip (18), and optional texturized/rubberized surface (19) as shown. Optional charge cable (15) and optional pencil sharpener (20) may each be independently present and when present are mounted generally on top portion underside (4a). Primary counters (11) and primary counter displays (11b), generally intended for opposing teams or opposing players (in two person sports) are located in the right hand and left hand corners of the top surface (6) for convenience, but may be located in any desirable portion of the top surface (6). Secondary counters (12) and their corresponding secondary counter displays (12b) are placed in FIG. 1 as shown, but may also be in other positions as desired. Each primary counter and each secondary counter is associated with a corresponding function button (12a) respectively, which is located along the side near the position of the respective display that it is associated with. In some embodiments, the respective counter, counter display, and/or function button can be incorporated into a prefabricated unit. In other embodiments, there are two counters, one associated with each of two teams and each having multiple function buttons associated with each such counters. Elements for fastening the tool (1) to the vertical support structure (2) (not shown) include “S hooks” (7a) and tethers (7d), which may include additional intermediary extensions of the tethers (7d) and/or “S hooks” (7a). The “S hooks” (7a) may be replaced by other suitable fastening elements such as, without limitation, speed clips (metal or plastic), suction cups, etc.

FIG. 1a shows the top view of a second embodiment of the present invention being a portable work station tool (1). The embodiment having a body member (3), being made up of a top portion (4) and a bottom portion (5) (not shown in FIG. 1a). The top portion (4) has a frame (100), enclosing a top work surface (6). The top work surface (6) having a top frame front (101), a top frame back (102), a top frame right side (103), and a top frame left side (104). The bottom member (5) has a bottom frame (207) made up of bottom frame front (207a), bottom frame back (207b), bottom frame right (207c), and bottom frame left (207d) portions. The bottom member (5) is of essentially the same dimensions as the top portion (4) and bottom portion (5) and top portion (4) are hinged to each other with attachment hinge (14) such that when the bottom member (5) is folded up to meet with top portion (4), the two mate appropriately to form a closed tool (1) that resembles an attaché case. In this embodiment, when the top portion (4) and the bottom portion (5) are folded together they form a convenient storage case that is portable and light weight. Attachment hinge (14) is generally attached by any suitable means to each of top portion (4) and to bottom portion (5), such as without limitation, rivets, nails, screws, etc., with rivets (27) being shown in FIG. 1a.

In FIG. 1a, primary counter (11) incorporates as a single prefabricated unit therewith, primary counter display (11b), secondary counter (12), and the corresponding function buttons (12a) while the single display in each unit acts as both the primary counter display (11b) and the secondary counter display (12b). The unit is held in place by housing holder (11a). Optional magnetic portions (7b) are placed along the top portion frame back (102) in embodiments where the fastening element (7) (such as, without limitation “S” hook” (7a) or a speed clip) is a metal that can be held in place by a magnet when the tool (1) is in a closed position for storage or transport. For safety considerations, the various corners are optionally rounded and optionally covered with molded plastic corners (22).

The top work surface (6) is divided into different regions for different purposes. In one portion, preferably located toward the right side of the work surface (6) is a wet/dry-erase surface (17) for keeping statistics and taking notes. For left handed writers, this may alternatively be located on the left side of the work surface (6). In a second portion of work surface (6). generally located to the left of the wet/dry-erase surface (17) is a texturized/rubberized, non-slip surface (19) typically for placement and use of smart devices (such as, without limitation, tablets, phones, iPods, laptops, etc.). In models designed for left handed writers, the placement of the texturized/rubberized surface (19) and the wet/dry-erase surface (17) are reversed so that the texturized/rubberized surface (19) is located on the right and the wet/dry-erase surface (17) is located to the left thereof. The placement of the other features on the work surface (6) may also be reversed between right and left to further accommodate left-handed users without departing from the present invention.

The entire work surface (6) may be fixed, or preferably may be optionally angled by the user for optimal use in viewing information on the work surface (6) and/or for ease of writing information on the work surface (6). Alternatively, each of the textured/rubberized surface (19) and the wet/dry erase surface (17) may be angled independently of one another, via use of suitable support members well known in the art. In an alternate embodiment, not shown, the work surface is removable and can be either rotated 180° and reinserted into appropriate clips or clamps or recesses to change a right-handed configuration to an essentially left handed configuration or vice-versa. In yet another embodiment, the work surface has one surface with the placement in a right handed orientation and an opposite face is a left handed orientation such that by flipping the work surface over the placement of the dry/wet erase board (17) and the texturized/rubberized surface (19) interchange their places and essentially convert a right-handed orientation to a left-handed orientation and back again.

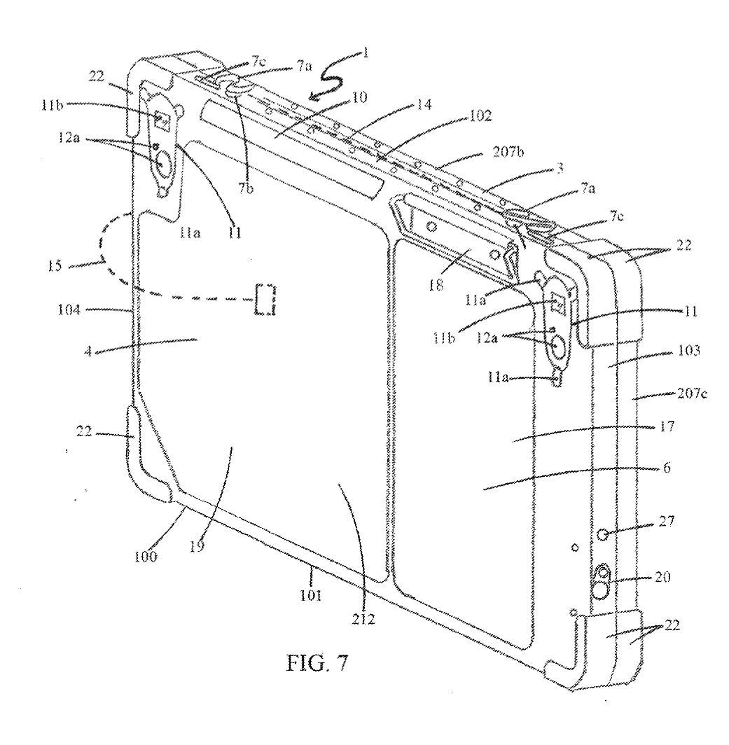

Along the top frame back (102) (or optionally along the top portion area located near the top frame back (102)) are at least two fastening elements (7) distally apart from one another for fastening the tool (1) to a fixed vertical support structure (2) (not shown in FIGS. 1 and 1a) such as, without limitation, a fence (such as a chain link fence), trellises, slatted doors, pegboard, etc. The fastening elements (7) can be any suitable fastener, but are preferably fasteners that can easily be removed from the vertical support (2), such as S-hooks, speed clips, suction cups, and/or any other such fasteners known in the art with respect to any appropriate, compatible mounting element used to secure the tool (1) to a vertical structure. Suction cups are suitable with respect to mounting and/or fastening to a smooth, solid surface of a vertical support structure. Along the top portion of the frame back are two oval openings (7c) (see FIGS. 7, 9, 14, and 20) cut into the top frame back (102) or alternatively one on each of the top frame right side (103) and top frame left side (104), preferably in top frame back (102) as connection points allowing for adjustment and easy access for any suitable type of fastener known in the art. Tethers (7d) are preferably built into these openings, but any other known securing mechanism can be used. Due to the accessibility, shape, and simplicity of the oval tether openings (7c), they are one preferred variant. Given a large assortment of fasteners available in the industry, many alternatives for the fasteners for use in the present invention are possible, and this aspect is highly customizable by the user to accommodate any application of securing the tool (1) to vertical structures. Auxiliary fasteners for supplemental use, securing the tool (1) to a horizontal surface, or the inclusion of optional additional legs that support the tool (1) from the ground, for additional versatility are optionally added, and the incorporation thereof is still within the scope of the invention. Preferred embodiments do not require such additional supports, such additional legs, or additional fasteners therefor.

In one embodiment, the vertical support member (8) can either be one or more legs (8) that are optionally foldable, collapsible, and/or removable with or without the aid of hinges and/or locking support braces (9). The two leg embodiment shown in FIGS. 1, 2, and 3, in which the legs (8) are distally apart from one another, extend downward from the interior of frame back (102) and/or the top portion underside (4a) is one suitable arrangement. In the single leg embodiment, the leg (8) is placed mid-way between the top left edge (104) and the top right edge (103), but the single leg embodiment is least desirable as it has the least stability in use unless it is the “wide leg” embodiment (such as, without limitation, that having bottom portion (5) acting as the support) described more fully below. Preferably, in single leg (8) embodiments, it is preferably for such single leg (8) to be of significant width or to have portions that fan out to the left and right of the leg (8) to provide additional support against the vertical support structure (2). Legs (8) preferably fold from the open position into the interior region bounded by top portion frame (100) or either by folding forward or folding rightward from the left side or leftward from the right side with appropriate support braces, hinges and hinge connectors (9, 9a) attached to the frame (100) and/or the top portion underside (4) and the particular leg (8) with appropriate support braces, hinges, and hinge connectors (9,9a). Alternatively, or in conjunction with the above, the legs (8a) can lock into the appropriate positions using button locks (not shown). Each of these versions of locking legs in place is well known from their use in collapsible card tables and other devices.

In a second embodiment, as shown in FIGS. 1a, 2a, 3, 4, 5, and 6-20, the bottom portion (5) operates as a vertical support member and is dimensioned to be the same front-to-back distance and the same left-to-right distance as the top portion (4), and is hinged by attachment hinge (14) to the top portion (4) so that on folding the top portion (4) and the bottom portion (5) together, the folded tool (1) of the invention resembles an attaché case. When opened and in use, the bottom portion (5) has bottom external surface (205) (which in the open-in-use position abuts the fixed vertical structure), bottom internal surface (206), and a bottom frame (207) therearound, the bottom frame (207) having a bottom frame left side (207d) and bottom frame right side (207c), with braces and/or hinges (9,9a) connecting (a) the bottom frame left side (208d) to the top portion frame left side (104) and bottom frame right side (207c) to the top portion frame right side (103) so as to maintain the tool (1) in a stable open position when in use. Alternatively, these hinges and braces can be used such that they connect (a) the bottom frame left side (207d) to the left side of top portion underside (4) or (b) the left side of the bottom surface (206) to the left side of top portion underside (4) or (c) the left side of the bottom surface (206) to the top portion frame left side (104). Similarly, the corresponding options for the placement of the right side hinge and hinge connector may be used. A single such brace and/or hinge (9) may be used, but is less desirable as it leaves the tool in a less stable condition in use.

In a third (most simplified) embodiment of the invention (shown in FIGS. 1b, 1c and 2b), top portion (6) is affixed near the back thereof to vertical support structure (2) by fastening elements (7a). The tool (1) has, in the shown embodiment, attachment cables (39), located on the right and left sides of top surface (6) which are connected to top surface (6) generally near the respective right and left edges thereof generally near the front edge of top (6). However, the connection of attachment cables (39) may be at any convenient location along the right and left sides of top surface (6). Nonetheless, when attachment cables (39) are used, they are preferably attached closer to the front edge of top surface (6) than the tool center of gravity. In the embodiment shown in FIG. 1b, the attachment cables (39) are used in place of both the vertical support member (8) and the bottom portion (5). Nonetheless, either or both, of the vertical support member (8) and the bottom portion (5) may be used in combination with the shown attachment cables (39) and/or the attachment hook (38). The embodiment shown in FIG. 1b is shown in a plain vanilla format, with none of the optional features discussed above. However, any of the optional features mentioned with respect to the other embodiments above can be used in conjunction with the embodiment shown in FIG. 1b. FIG. 1c is the same view as FIG. 1b, except that in FIG. 1c dry erase board (17), textured surface (19), and pencil/paper clip (18) are shown in place in one orientation.

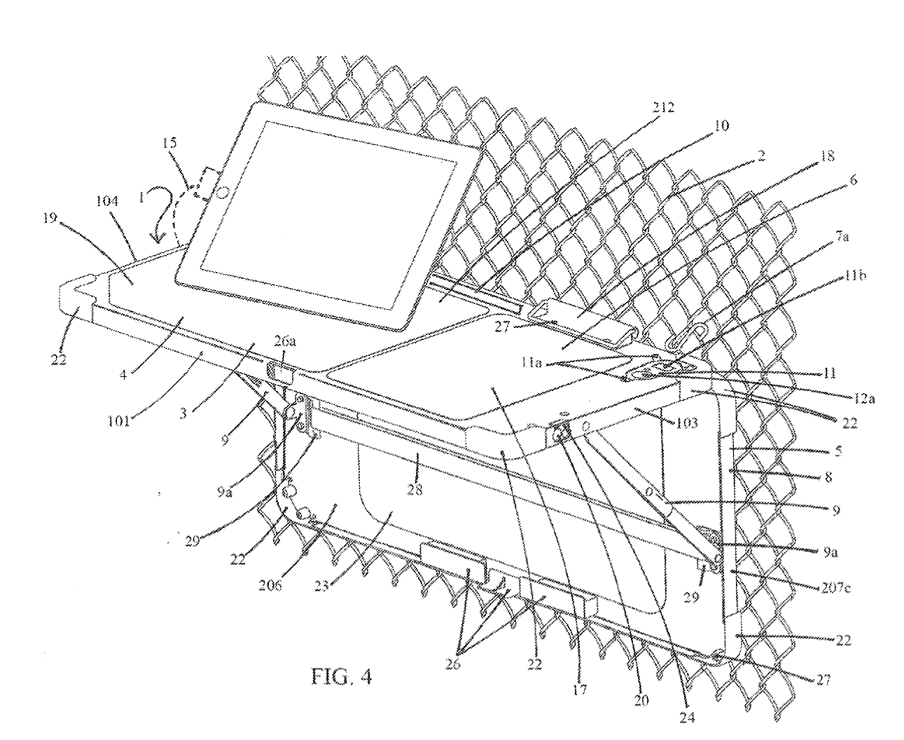

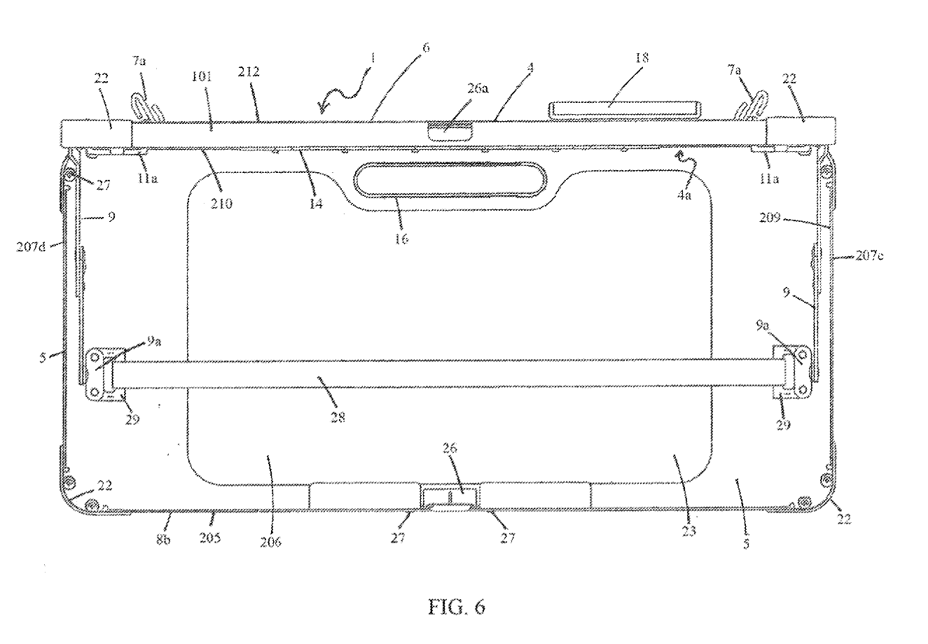

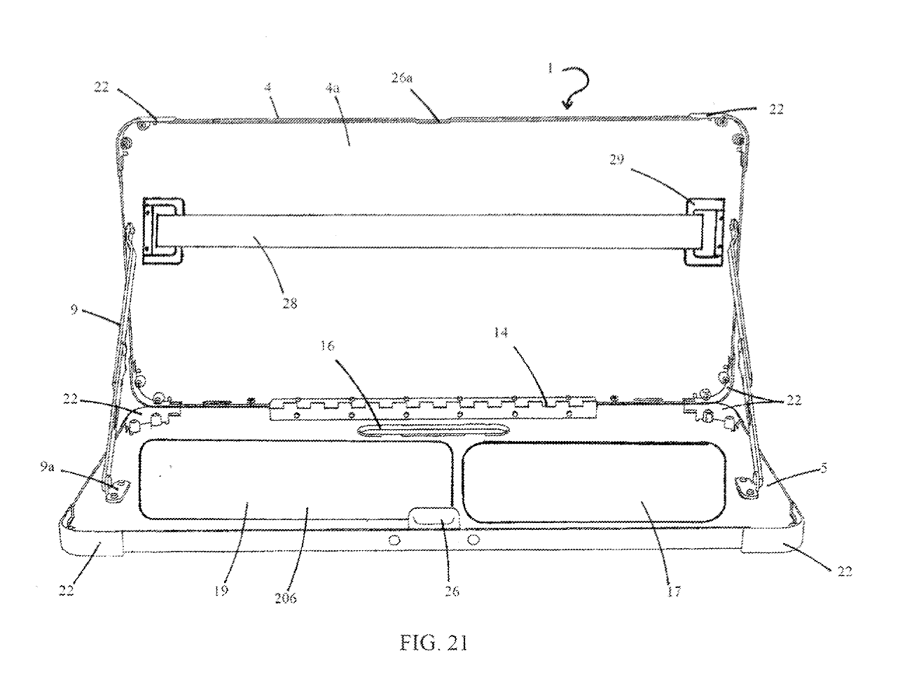

In yet a further embodiment of the invention shown in FIG. 21, the tool (1) is a variant of the “attaché case” type shown in FIG. 1a except that instead of the work surface being top work surface (6), the work surface is contained on the interior of the attaché case. In this embodiment, top portion (4) does not have the features shown as being on the top work surface (6) in the other figures, but does have the fastening elements (7a) along top frame back (102) and optionally additional fastening elements (7a) at or near the front right and left corners near the elements (22). These fastening elements (and optionally additional fastening elements allow top portion (4) to be affixed to vertical support structure (2) with the optional additional fastening elements (7a) that are closest to the front being affixed to a portion of structural support (2) that is vertically higher than that to which the fastening elements (7a) that are on top frame back (102). In FIG. 21, none of these fastening elements (7a) are in view. Once attached to the vertical support structure (2), the tool (1) can be opened by releasing latch (26) and lowering the bottom portion (5) to a horizontal portion. In the horizontal position, the interior surface of bottom portion (5) provides the replacement work surface. In FIG. 21 for simplicity, only the positioning of the texturized surface (19) and wet/dry erase board (17) are shown. However, all or some subset of the features previously identified on top work surface (6) with reference to the embodiment shown in FIG. 1a are present on the bottom portion interior surface (206) which operates as the work surface (6) in the present embodiment. Elements that were shown on bottom portion interior surface (206) (as in FIG. 4 and others) are either eliminated or moved to the top portion underside (4a), which is, in the open position, in a vertical rather than (as shown in the embodiment of FIG. 6) in a horizontal position. In this orientation, the top portion (4) acts as a vertical support against the vertical support structure (2), reinforcing the support obtained from four support elements (7a). In this embodiment, if desired the two support elements (7a) that are located along the top back (102) can be omitted if the “additional support elements (7a)” are present, or all four can be present, if desired. If further support is desired, additional support legs (8) (not shown) which can telescope into the top portion (4), or fold along the bottom portion exterior surface for transport may be added. Alternatively, a panel may be recessed within top portion (4) which panel may be extended from top portion (4) once the tool (1) is attached to the vertical support structure (2) where the panel extends vertically downward to provide additional support against the vertical support structure (2). In these embodiments, the interior surface (206) of bottom portion (5) is optionally, but preferably, constructed so as to be substantially level (or flush) with the bottom portion frame so that the bottom portion frame does not form a significant lip to interfere with the user of the tool (1).

The remaining features, are all optional depending upon the particular context of use in which one wishes to use the tool (1). Nonetheless, the most preferred embodiments utilize all or substantially all of the following additional features. These features will be discussed in the context of a baseball/softball/stickball scoring tool, but as will be apparent to those of ordinary skill, minor variations, primarily in the labels of various features or in modifications of the operations of various counters or in software operating such counters, the tool (1) is equally applicable to use as a scoring tool in virtually any sport or competitive activity, whether for individual competitors or for team activities, whether physical competitions or mental competitions, each of which is deemed within the scope of the present invention. In addition, the instant invention is also equally applicable to any environment of use in which a portable work station that can be secured quickly and easily to a vertical support structure is desirable, especially in those contexts where the vertical support is a fence or pegboard or similar structure. These include, without limitation, construction sites, medical facilities, combat zones, and field work of many different types.

A first optional feature for the present invention tool (1) is the presence of a solar cell or strip (10) which is located on any available surface which will be exposed to light, preferably exposed to sunlight when the tool (1) is in use. Thus, the solar cell or strip (10) can be located on portions of the top portion (4) that is not occupied by another feature. In embodiments having the bottom external surface (205), the solar cells or strip (10) can be located on surface (205), which either allows for additional solar cells for additional power generation or allows for one to omit the solar cells or strip (10) from the top portion (4), freeing up more of the work surface for other purposes. The solar cells or strip can be of any conventional design known in the art.

A rechargeable power supply storage unit which may either simply be conventional replaceable batteries or rechargeable batteries, with the rechargeable batteries being rechargeable from the power generated by the solar cells or strip (10) or via a power cord available to plug into a suitable power source. The rechargeable power supply can be stored in power supply storage unit (13) which can be located at any convenient position either on the underside of the work surface (6) or on the bottom internal surface (206). Preferably, it is located at a position making the connections between it and the solar cell strip (10) as well as between it and the various power usage features convenient.

Preferably, a handle (16) is built into the tool (1). It can be located at any convenient edge for carrying purposes. In embodiments having single leg member (8b), the handle can be built into either or both of the top portion (4) and the single leg (8b). The handle can either be a cutout in the work surface (6) and/or the corresponding region of the bottom portion (5), or alternatively can be a handle that is added to any of the frame external surfaces i.e., elements (201), (202), (203), or (204) and/or the corresponding portions of the bottom frame (207) in embodiments having the bottom portion (5). Preferably, the handle is located either (a) at the front portion (near the front edge (101)) of the top portion (4) and/or the front portion (near the bottom portion front edge (207a)) of bottom portion (5) or the back portion (near the back edge (102)) of the top portion (4) and/or the back portion (near the bottom portion frame back (207b) of bottom portion (S). The handles are located generally close to the center of gravity of the tool (1) when in a carrying position for ease of balance, but the exact placement is not critical. Clips for shoulder straps (not shown) for alternate carrying configurations may be added as desired. A latching mechanism is included to maintain the tool in the folded, closed position for transit, especially when it is one of the embodiments that have a bottom portion (5) and the handle does not include grasping both the top portion (4) and the bottom portion (5). While some locations of the handle in these embodiments do not require the latching mechanism, it is preferably present to keep the bottom portion (5) and the top portion in a closed position. However customized for this invention, such latching/locking mechanisms are well known and readily adopted from the luggage and attaché case arts.

In a first embodiment, primary counter displays (11,12), are generally present and generally located near the two corners of the top portion (4) that are near the top portion back edge (102). When using for a team sport or two person competitions, one is relegated to the home team or one individual, and the other is relegated to the away team or opponent. The displays can be of any desired type, but are preferably LCD displays. While the displays can be placed on any available free space on the top portion (4), their placement as stated above has been found to be most convenient. If desired, additional such counters can be added. Function buttons (12a) for activation of the counter displays are located near the displays (11b,12b) on the frame side (left or right) nearest the particular display.

In a second embodiment, the tally/pitch counters, as used in relation to baseball, softball, stickball and the like, are built into the top portion (4) in a replaceable and serviceable fashion which are secured in a removable housing holder (11a), (such as to change a battery) in the right and left corners near the back edge (102).

In the first embodiment, various optional, additional buttons (12a) are present on the top portion (4) for recording information for the appropriate counter displays (11b,12a). For the baseball/softball/stickball configuration, there are four buttons, one for each of inning, balls, strikes, and outs. Additional buttons can be added if desired for recordation of errors, walks, steals etc. If desired, software can be added to reconfigure the various buttons for other sports. The buttons (12a) can be hard labeled if desired, or have displays associated with each that can be changed as desired depending on the sport or activity for which the tool (1) is being adapted for use. The various buttons can, if desired, be integrated together with the respective secondary displays.

In another embodiment, where the use of a tablet or other smart device may be used in game scoring, the incorporation of the additional four buttons may or may not be desirable and therefore may or may not be present.

A pencil/pen/marker holder clip and/or paper clip (18) may be present on the work surface (6) and is generally located near the margin of the wet/dry erase surface that is closest to the back edge (102).

A pencil sharpener may also be present and is generally recessed within front edge (101). While it may be located at any available position along front edge (101), for convenience, in right hand models it is located near the frame right side (103), and in left hand models it is located near frame left side (104). The pencil sharpener may be a manual one or a powered one, powered by the various power sources discussed above.

As shown in a second embodiment, the orientation of the pencil sharpener (20) is located in the top portion (4) recessed into the top right frame side (103) and secured with a (preferably plastic) housing (24).

Storage compartments of various sizes and shapes for useful items can be incorporated on the underside of the work surface (6), or attached to any available space on the bottom portion (5) internal surface (206) (when the bottom portion (5) is present).

As shown in the second embodiment, there are areas dedicated to storing specific accessories such as, but not limited to, rechargeable battery, charging cable, tablet, smart device, writing implements or scorebooks etc.

As shown in the second embodiment, there is present internal storage space (100a) with an elastic band/keeper (28) to secure stored accessories.

A foldable/collapsible convenience cup holder (21) can be integrated into the tool (1) by having a slot (21a) in any available position of the frame right side (103) or the frame left side (104). The slot (21a) can accommodate a clip for a cup holder or contain a movable cup holder that moves out of the slot. In embodiments having large enough surface areas (not shown), a portion of the top portion (4) can be recessed so as to receive the bottom of a cup therein.

FIG. 2 is a left side view of the embodiment in FIG. 1 showing the vertical support (8) as being movable from the shown in-use position to the stored non-use position, the work surface (6) being movable between a raised angled position and a flat position, the cup holder slot (21a) and removable cup holder (21), function button (12a), tether (7d), and “S” hook (7a).

FIG. 2a is a left side view of the embodiment of FIG. 1a showing essentially the same features as shown in FIG. 2 except that bottom portion (5), corner pieces (22), latch (26), counter housing holder (11a), pencil/paper clip (18), attachment hinge (14), locking hinge/support brace (9), are shown, while function buttons (12a), having been incorporated into a prefabricated counter housing are not visible in this view. Also shown in this view are mechanical connectors (27) such as, without limitation, rivets. In a number of the drawings the mechanical connectors are shown, but not all are labelled.

FIG. 2b is a perspective view of the embodiment shown in FIG. 1b in a non-use storage, but still mounted position.

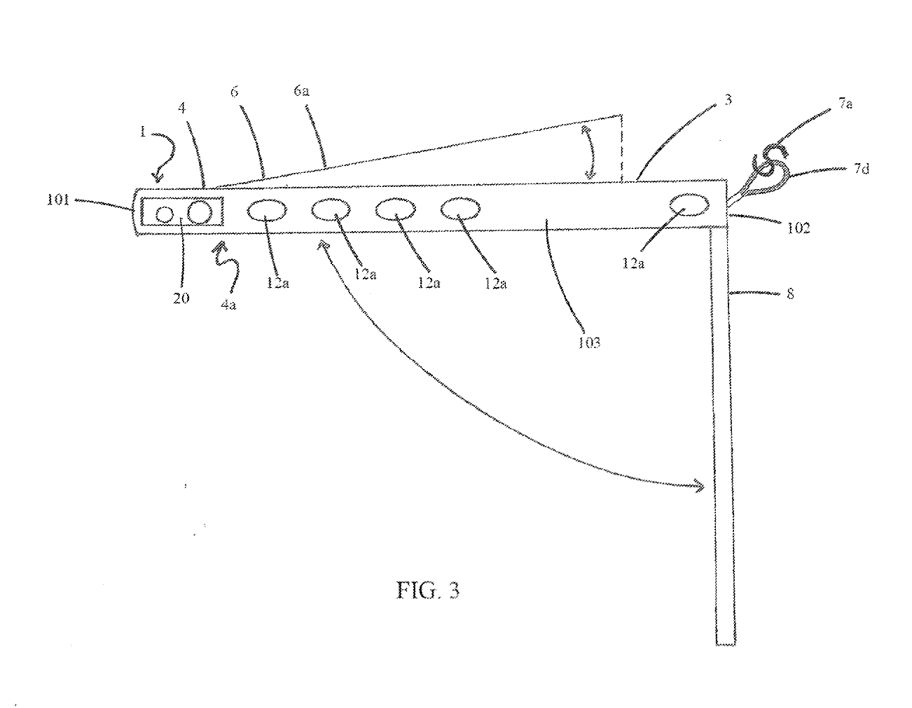

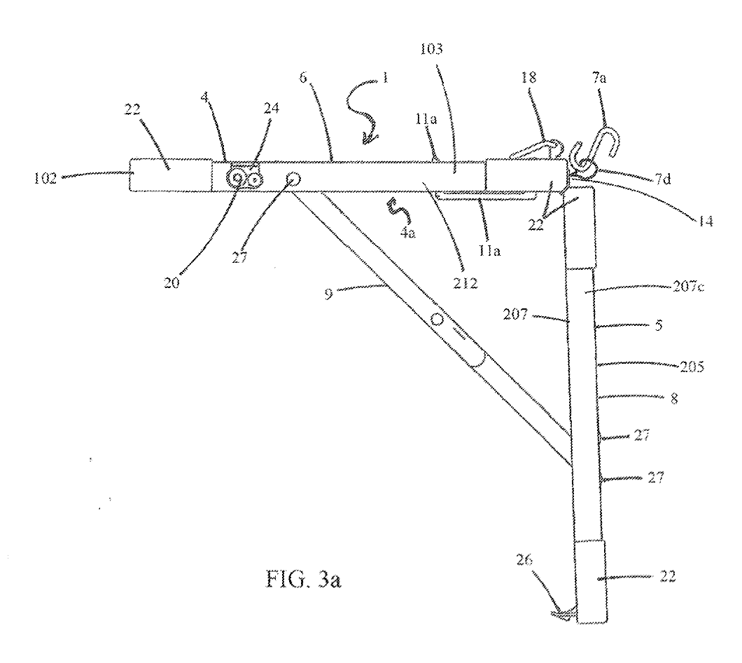

FIG. 3 is a right side view of the embodiment of FIG. 1 showing one type of placement of individual function buttons (12a) and pencil sharpener (20).

FIG. 3a is a right hand view of the embodiment in FIGS. 1a and 2a showing essentially the same elements as therein with the addition of one placement of the pencil sharpener (20) and pencil sharpener holder (24), pencil/paper clip (18), and counter holder (11a).

FIG. 4 is a perspective view of the embodiment in FIG. 1a in an open position mounted on (chain link) fence (2). In addition to features shown in earlier figures, optional charging cable (15) is shown connected to an optional tablet device, storage band (28), hinge connectors (9a), and mechanical fasteners (29) for storage band (28) are depicted.

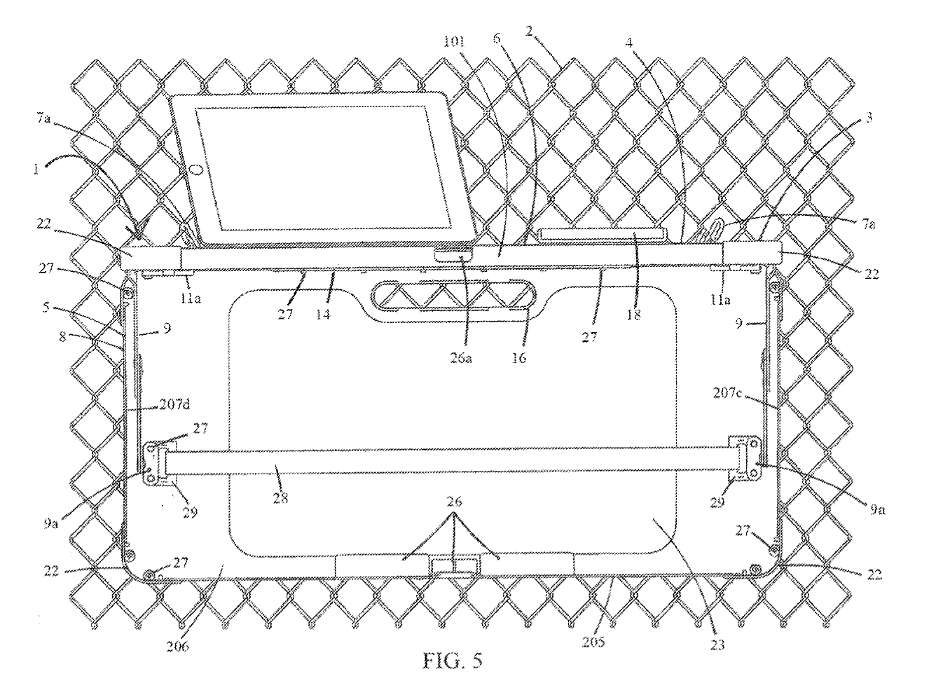

FIG. 5 is a straight on front view of the embodiment in FIG. 4 allowing a view of handle (16), not visible in FIG. 4, and showing latch (26) and latch opening or receiver (26a).

FIG. 6 is similar to FIG. 5 except that the background “fence” (2) is eliminated for clearer viewing and “lined protective interior surface” (23) is shown.

FIG. 7 is a perspective view of the embodiment of FIG. 1a in a closed position with top (4), top right side (103), bottom portion right side (207c), top back (102), and bottom back (207b) in view, and shows attachment hinge (14) and its associated rivets (27) and openings (7c) and magnets (7b) more fully.

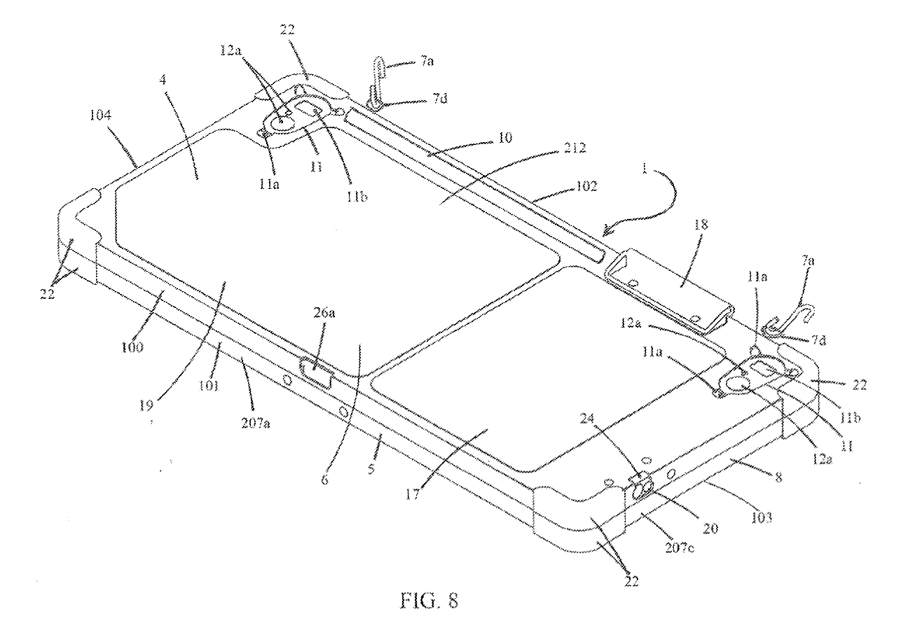

FIG. 8 is a perspective view of the embodiment shown in FIG. 7 laying down in a horizontal position with top (4), top portion front (101), bottom portion front (207a), top right side (103), and bottom portion right side (207c) in view.

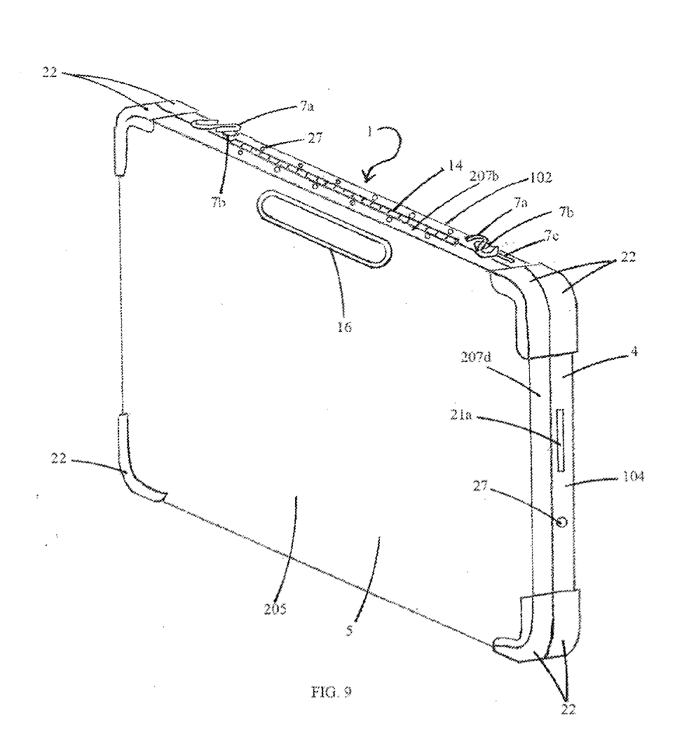

FIG. 9 is a perspective view of the embodiment in FIG. 7, viewed from the rear in which bottom external surface (205), top back (102), bottom portion back (207b), top left side (104), and bottom portion left side (207d) are in view.

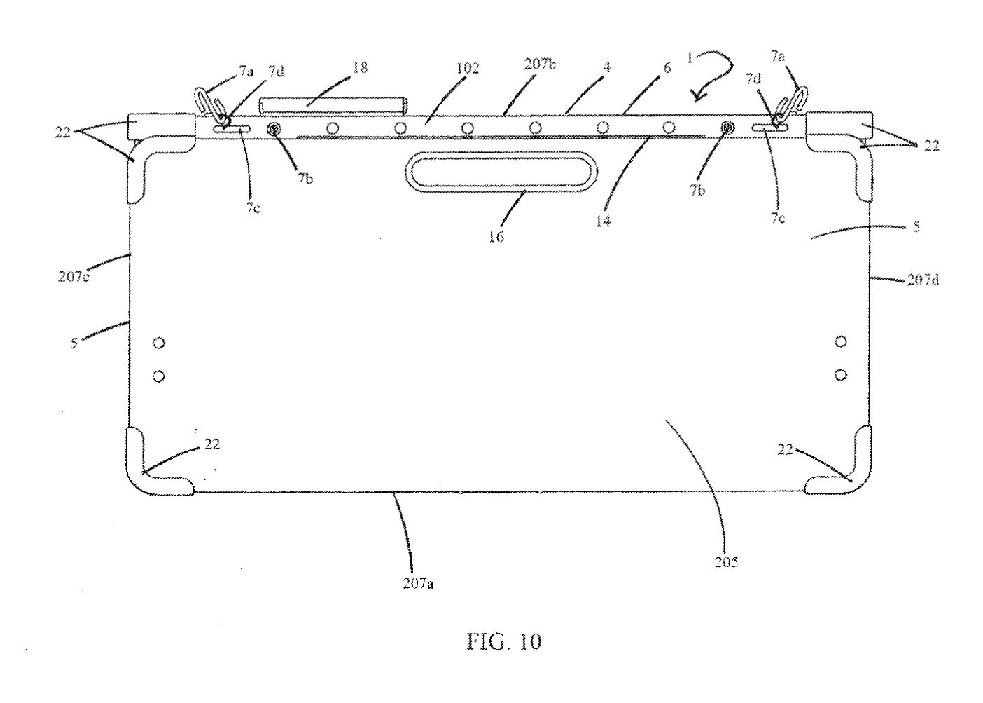

FIG. 10 corresponds to FIG. 6 except that FIG. 10 is a view from the back.

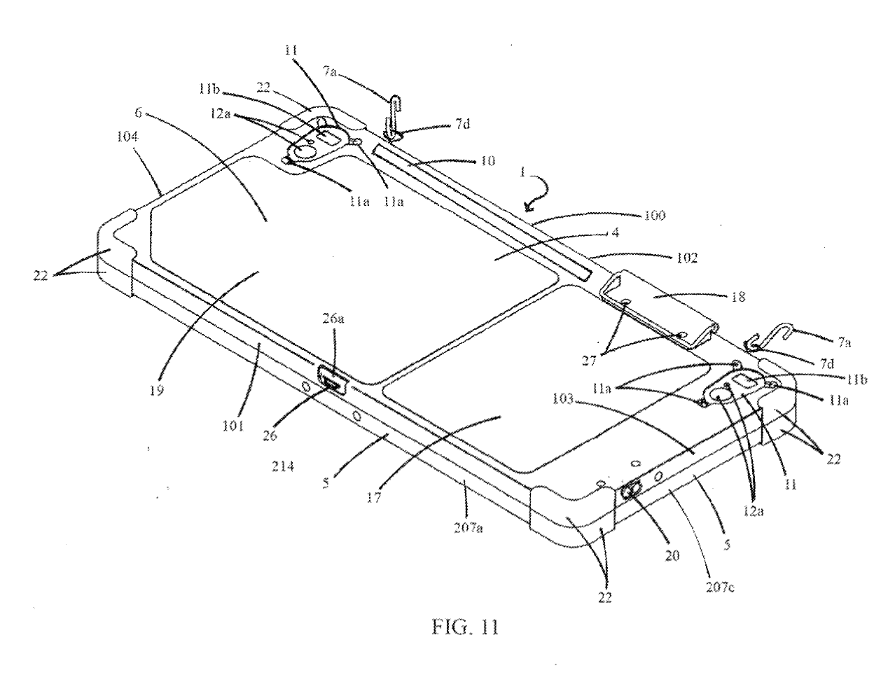

FIG. 11 corresponds substantially to FIG. 6.

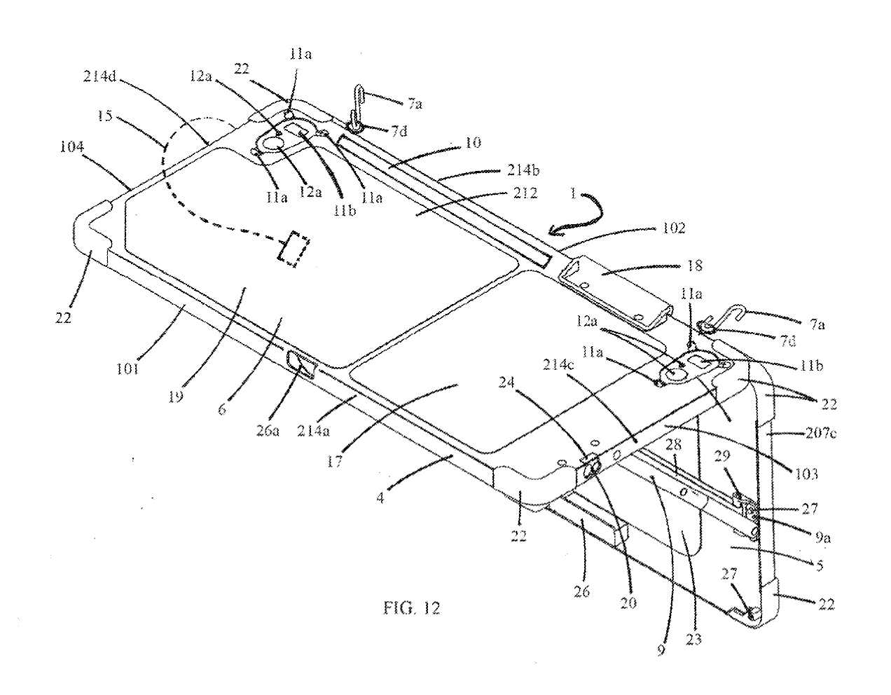

FIG. 12 corresponds essentially to FIG. 4 without the background fence and eliminating the optional tablet for a better view of top surface (4), left hand side.

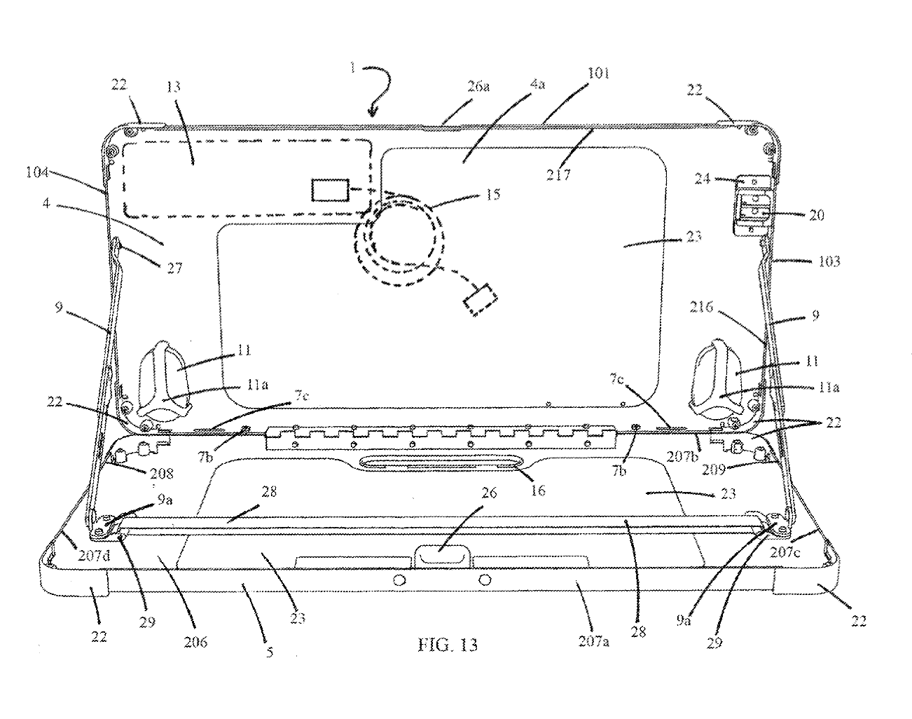

FIG. 13 is a view of the embodiment of FIG. 12 when viewed from underneath showing rechargeable power supply/battery storage (13) and charger cord (15) in one orientation on the top portion underside (4a) and the mounting of counters (1) and their respective holders (11a) on top portion underside (4a). Also shown is one placement orientation of affixing locking mechanical hinges (9) to top portion (4) and to bottom portion (5).

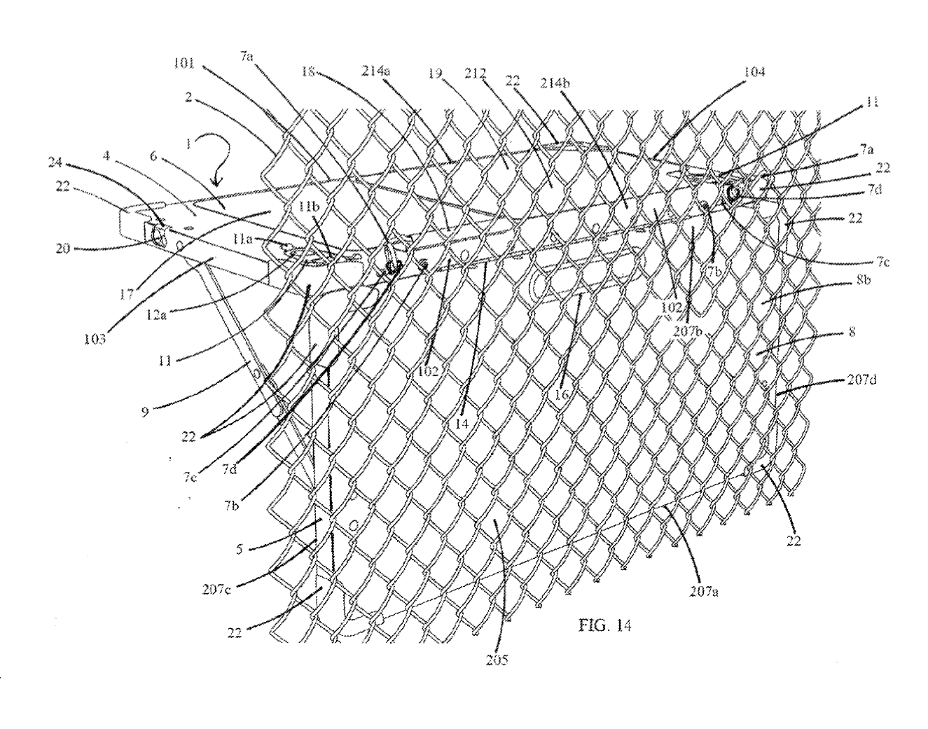

FIG. 14 is a rear view of the embodiment shown in FIG. 4, except that the optional tablet shown in FIG. 4 is not present.

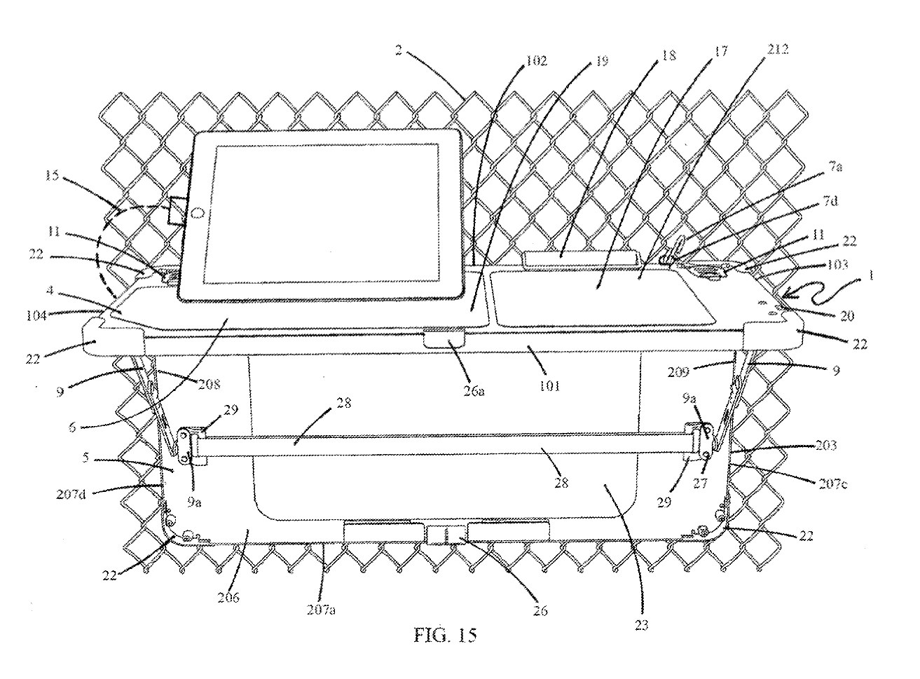

FIG. 15 is a perspective view corresponding essentially to FIG. 4 except that the view is more of a frontal view.

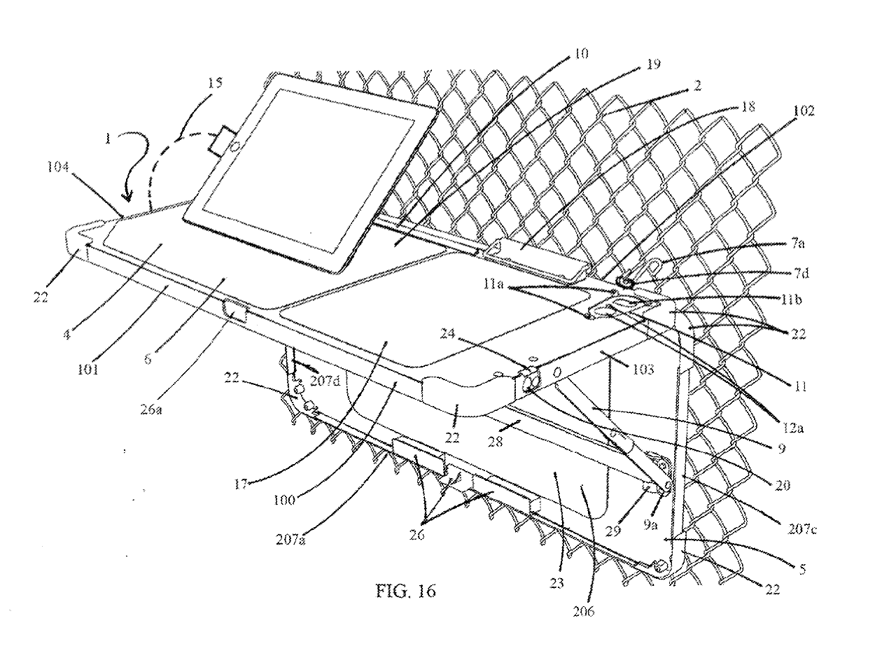

FIG. 16 also corresponds essentially to FIG. 4, except that FIG. 16 is a more oblique perspective.

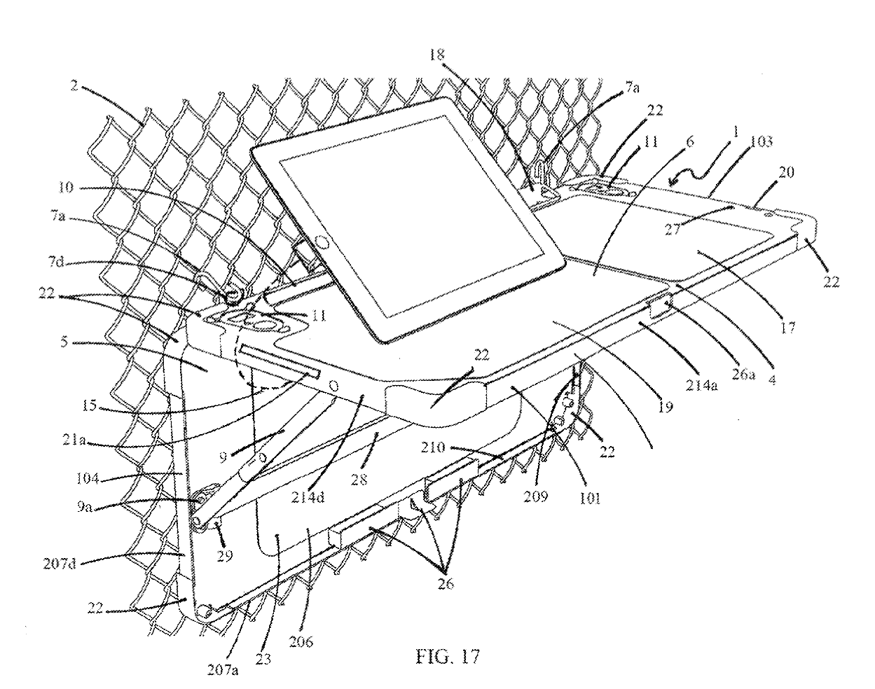

FIG. 17 further corresponds to FIG. 4 except that this is a perspective view from the left side.

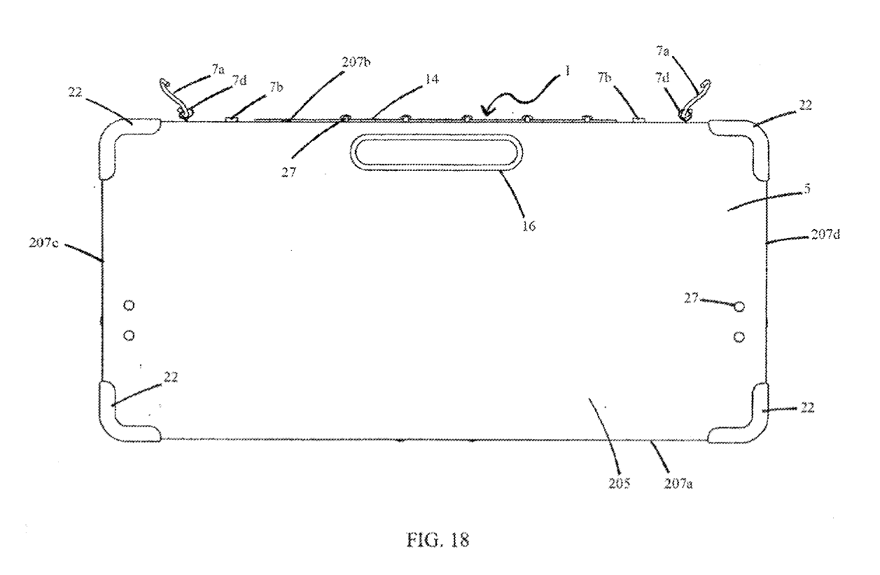

FIG. 18 corresponds to FIG. 9 except that FIG. 18 is a rear plan view of the embodiment in a closed position and viewed from the rear showing bottom portion external surface (205).

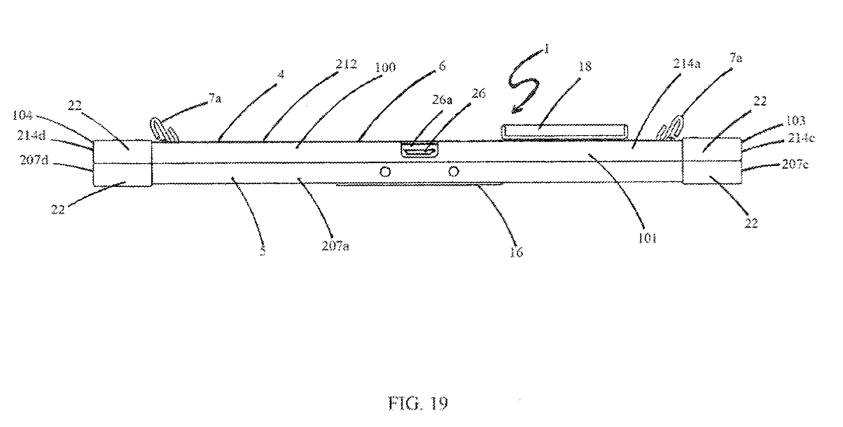

FIG. 19 is a front view of the embodiment shown in FIGS. 18 and 9 in a closed position and showing top portion front (101) and bottom portion front (207a).

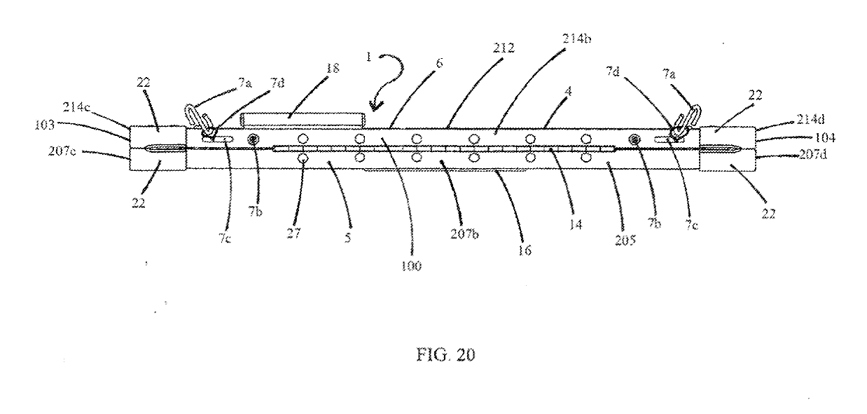

FIG. 20 is a rear view of the embodiment shown in FIGS. 19, 18, and 9 in a closed position and showing top portion back (102) and bottom portion back (207b).

The foregoing discussion discloses and describes merely exemplary embodiments of the present invention. The embodiments depicted herein are illustrative and modifications to such embodiments within the skill of those in the art are encouraged by the present application. One skilled in the art will readily recognize from such discussion, and from the accompanying drawings and claims, that various changes, modifications and variations can be made therein without departing from the spirit and scope of the invention as defined in the following claims.

We claim:

1. A portable work surface tool, comprising:
(A) a body member having a top portion having a front, a back, a right side, a left side, a width bounded by said right side and said left side, and a depth bounded by said front and said back, comprising
(i) a top surface defining a work surface and
(ii) an underside surface;
said top having
(a) at least one fastening element operatively associated with said body member, said fastening element being configured for secure engagement with a fixed portion of a vertical structure; and
(B) at least one vertical support member being
(i) one or more leg members extending from or within said top portion and/or
(ii) a bottom portion having a bottom portion front, a bottom portion back, a bottom portion right side, a bottom portion left side, a bottom portion width bounded by said bottom portion right side and said bottom portion left side, and a bottom portion depth bounded by said bottom portion front and said bottom portion back, said bottom portion width being about the same size as said top portion width and said bottom portion depth being about the same size as said top portion depth, said bottom portion being hingably attached along said bottom portion back to said top portion back, whereby said bottom portion and said bottom portion can hingably move between a first closed position and an open second position, so that when in said first closed position, said work surface tool resembles an attaché case, and in said second open position, said bottom portion operates as a vertical support member, and/or
(iii) a recessed panel within said top portion, which recessed panel extends in a downward manner once said tool is attached to said fixed vertical structure,
said vertical support member (i), (ii), or (iii) being configured for an extended or open position for operative engagement with the vertical structure to maintain the work surface in a generally horizontal-directed orientation and/or
(iv) attachment cables and/or
(v) additional fastening elements.

2. The portable tool of claim 1 wherein the at least one leg member is pivotably movable from an extended position to a position flat against the body member.

3. The portable tool of claim 1 wherein the at least one leg member is pivotably movable from an extended position to a position concealed within the body member.

4. The portable tool of claim 1 wherein the at least one fastening element is a clip-type fastener.

5. The portable tool of claim 4 wherein the clip-type fastener is a speed clip.

6. The portable tool of claim 1 wherein the body member comprises a solar panel assembly for generating electricity.

7. The portable tool of claim 1 further comprising a rechargeable electric power source.

8. The portable tool of claim 7 further comprising a power adapter electrically connected to the rechargeable electric power source for supplying electricity to an electronic device.

9. The portable tool of claim 1 further comprising a counter mechanism, and a panel display operatively associated with said counter mechanism for displaying count information.

10. The portable tool of claim 1 wherein the work surface comprises a textured surface.

11. The portable tool of claim 1 wherein the work surface includes a smooth surface adapted for reversibly retaining thereon a removable marking.

12. The portable tool of claim 1 further comprising a recessed pencil sharpener.

13. The portable tool of claim 1 wherein the body member further comprises a rigid frame extending along a peripheral edge thereof.

14. The portable tool of claim 13 wherein the rigid frame is composed of a metal material, a plastic material, or a combination thereof.

15. The portable tool of claim 14 wherein the rigid frame is selected from the group consisting of an anodized rigid frame, a powder-coated frame and/or combinations thereof.

16. The portable tool of claim 1 wherein the work surface comprises a clamp adapted for holding paper and/or pencil.

17. The portable tool of claim 1 further comprising a handle disposed on the body member.

18. The portable tool of claim 1 wherein the work surface is pivotably movable from a flat position to an upright position.

19. The portable tool of claim 1 further comprising a cup holder.

20. The portable tool of claim 1 further comprising a storage space located within said body member.

21. The portable tool of claim 1 further comprising lined protective interior surfaces for protection of objects being stored therein.

22. A portable work surface tool comprising
(A) a body member having a top portion having a front, a back, a right side, a left side, a width bounded by said right side and said left side, and a depth bounded by said front and said back, comprising
(i) a top surface defining a work surface and
(ii) an underside surface;
said top having
(a) at least one primary fastening element operatively associated with said body member, said primary fastening element being configured for secure engagement with a fixed portion of a vertical structure; and
(b) at least one secondary fastening element operatively associated with said body member, said secondary fastening element being configured for secure engagement with a fixed portion of a vertical structure;
said at least one primary fastening element being connected to said body member at said back or on said top surface near said back and said secondary fastening element being connected to said body member (a) along said right side or (b), along said left side, or (c) two such secondary fastening members being used one on said right side and one on said left side or (d) along said front near said left side or (e) along said front near said right side, or (f) two such secondary fastening elements being used along said front, one near said right side and one near said left side; said primary and secondary fastening elements capable of independently being fastened to a stationary vertical support structure; wherein, when the primary fastening elements and secondary fastening elements are engaged with a fixed vertical support structure, said tool can adopt a first substantially horizontal position suitable for use as a work surface.
